(19) United States
(12) Patent Application Publication
(10) Pub. No.: US 2013/0256509 A1
(43) Pub. Date: Oct. 3, 2013

(54) DUAL SOURCE FOLLOWER PIXEL CELL ARCHITECTURE

(71) Applicants: Cunyu Yang, Milpitas, CA (US); Howard E. Rhodes, San Martin, CA (US)

(72) Inventors: Cunyu Yang, Milpitas, CA (US); Howard E. Rhodes, San Martin, CA (US)

(73) Assignee: OMNIVISION TECHNOLOGIES, INC., Santa Clara, CA (US)

(21) Appl. No.: 13/431,600

(22) Filed: Mar. 27, 2012

(51) Int. Cl. H01L 27/148

(52) U.S. Cl. 250/208.1

(57) ABSTRACT

Techniques for providing a pixel cell which includes two source follower transistors. In an embodiment, a first source follower transistor of a pixel cell and a second source follower transistor of the pixel cell are coupled in parallel with one another, where the source follower transistors are each coupled via their respective gates to a floating diffusion node of the pixel cell. In another embodiment, the first source follower transistor and second source follower transistor each operate based on a voltage of the floating diffusion node to provide a respective component of an amplification signal, where the pixel cell outputs an analog signal based on the amplification signal.

### BACKGROUND OF THE INVENTION

1. Field of the Invention

This disclosure relates generally to image sensors, and in particular but not exclusively, relates to CMOS image sensors.

2. Background Art

Image sensors have become ubiquitous. They are widely used in digital still cameras, cellular phones, security cameras, as well as medical, automobile, and other applications. The demands of higher resolution and lower power consumption have encouraged further miniaturization and integration of these image sensors. As a result, technology used to manufacture image sensors, for example, CMOS image sensors (“CIS”), has continued to advance at a great pace.

FIG. 1 is a circuit diagram showing pixel circuitry 100 including two four-transistor (“4T”) pixel cells—Pa 110 and Pb 120—of a conventional pixel array. In FIG. 1, pixel cells Pa 110 and Pb 120 are arranged in two rows and one column. Pa 110 and Pb 120 each include the same conventional pixel cell architecture in which each pixel cell includes a photosensitive element PD, a transfer transistor T1, a reset transistor T2, a source-follower (“SF”) transistor T3, and a select transistor T4.

During operation of Pa 110 (or similarly, Pb 120), transfer transistor T1 receives a transfer signal TX, which transfers charge accumulated in PD to a floating diffusion node FD. T2 is coupled between a power supply VDD and FD to reset the pixel (e.g., to discharge or charge FD and/or PD to a preset voltage) under control of a reset signal RST. FD is also coupled to control the gate of T3. T3 is coupled between power supply VDD and T4. T3 operates as a source-follower providing a high impedance connection to FD. Under control of a select signal SEL, T4 selectively provides an output of the pixel cell (one of Pa 110 and Pb 120) to a readout column line.

PD and FD are reset by temporarily asserting the reset signal RST and the transfer signal TX. An image accumulation window (exposure period) is commenced by de-asserting the transfer signal TX and permitting incident light to charge PD. As photo-generated electrons accumulate on PD, its voltage decreases. The voltage or charge on PD is indicative of the intensity of the light incident on PD during the exposure period. At the end of the exposure period, the reset signal RST is de-asserted to isolate FD and the transfer signal TX is asserted to allow an exchange of charge between PD and FD, and hence the gate of T3. The charge transfer causes the voltage of FD to change by an amount which is proportional to photogenerated electrons accumulated on PD during the exposure period. This second voltage biases T3 which, in combination with the select signal SEL being asserted, drives a signal from T4 to the readout column line. Data is then readout from the pixel cell (one of Pa 110 and Pb 120) onto the readout column line as an analog signal.

Typical fabrication of a source follower transistor such as T3, at some stage, provides for or otherwise includes a comparatively uniform concentration of a dopant (e.g. boron) across a portion of an active area in a semiconductor substrate, where the active area is for the source follower transistor and where the portion extends between isolation structures which adjoin the active area. However, some later stage in pixel cell fabrication may reduce the uniformity of such a dopant concentration. For example, one or more heat cycles may cause at least some of the dopant to migrate from the active area into one or more adjoining isolation structures. Such migration is more likely for dopant which is initially located closer to an isolation structure—e.g. as compared to dopant which is located closer to the middle of the active area. Consequently, a comparatively less uniform dopant concentration in the active area may result, where the dopant concentration at a location closer to the middle of an active area tends to be higher than the active area dopant concentration at a location which is closer to an adjoining isolation structure.

When a conventional poly gate for the source follower transistor is formed over such an active area, operation of the transistor can be affected by the variation in dopant concentration across the active area—e.g. where a portion of the gate which is near an edge of the active area may have a lower threshold voltage than that of another portion which is closer to the middle of the active area. As a result, operation of such a transistor may be characterized by three different channel regions, where one channel region extends along a middle portion of the active area and the two other channel regions each extend along different respective edges of the active area. The channel region extending along the middle portion of the active area may have a higher threshold voltage than that of either of the other two channel regions. Current being carried along an edge channel region has an increased likelihood of charge trapping/releasing along an interface between the active area and an adjoining isolation region. Such trapping is one source of random telegraph signal (RTS) noise in transistors.

Generally speaking, miniaturization in image sensors results in smaller photodiodes which generate smaller amounts of charge for smaller amounts of incident light, where signals of smaller voltage and/or current levels are in turn generated for representation of the captured image. Such smaller signals are more susceptible to various types of noise such as RTS noise. Effectively generating and processing such signals poses one challenge for next-generation image sensors.

### BRIEF DESCRIPTION OF THE DRAWINGS

The various embodiments of the present invention are illustrated by way of example, and not by way of limitation, in the figures of the accompanying drawings and in which:

FIG. 1 is a circuit diagram illustrating pixel circuitry of two 4T pixels in a conventional image sensor.

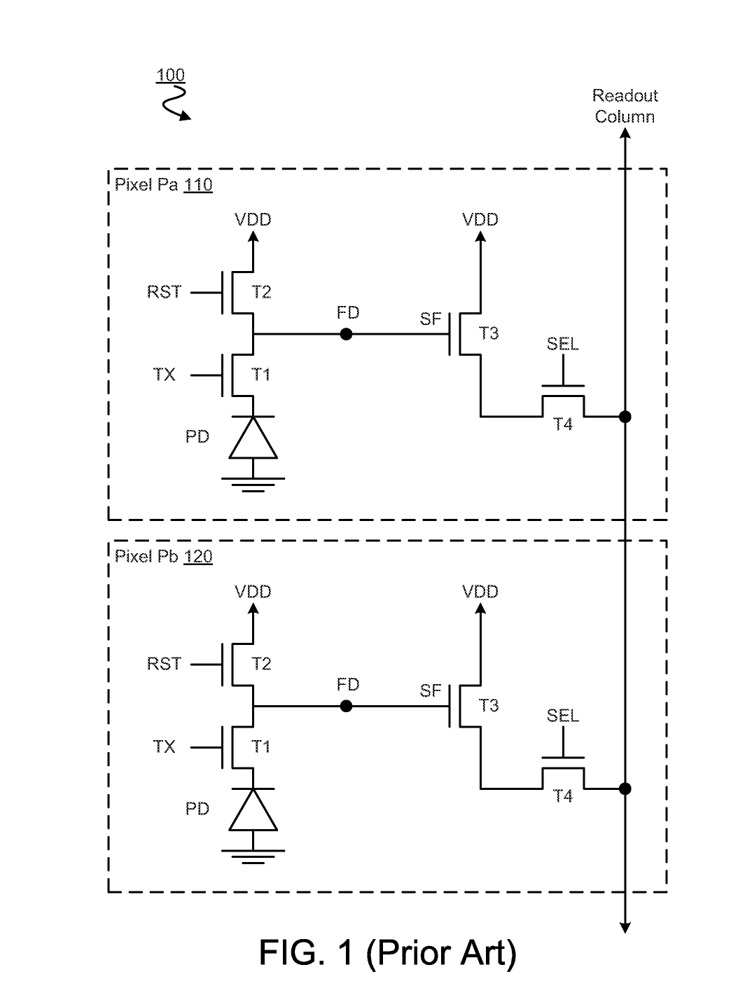

FIG. 2 is a block diagram illustrating elements of an imaging system according to an embodiment.

FIG. 3 is a circuit diagram illustrating elements of a pixel cell according to an embodiment.

FIG. 4 is a layout diagram illustrating elements of a pixel cell according to an embodiment.

FIG. 5 is a flow diagram illustrating elements of a method for operating a pixel cell of an image sensor according to an embodiment.

### DETAILED DESCRIPTION

Certain embodiments discussed herein variously provide for a pixel cell architecture including two source follower transistors, each to contribute to an amplification signal of the pixel cell. A pair of source follower transistors of a pixel cell may, for example, be coupled in parallel with one another, where the respective gates of the source follower transistors are each coupled to a floating diffusion node of the pixel cell. In such an embodiment, operation of the dual source follower transistors may be based on the floating diffusion node transitioning to a voltage level corresponding to an amount of charge accumulated in a photodiode of the pixel cell. Parallel source follower transistors of a pixel cell may, in an embodiment, share an active area (e.g. including a diffusion well or other such structure) in a semiconductor substrate for the pixel cell—e.g. where respective structures of the first and second source follower transistors are variously formed in and/or on the same active area. In an embodiment, the active area is bounded by one or more isolation structures adjacent thereto—e.g. including one or more shallow trench isolation (STI) structures formed in the semiconductor substrate. In another embodiment, two source follower transistors of a pixel cell may each comprise structures formed in and/or on different respective active areas of a semiconductor substrate.

Two source follower transistors, coupled to operate in parallel with one another, may provide a pixel cell according to an embodiment with limited susceptibility to the effects of RTS noise—e.g. as compared to a conventional pixel cell. Two such source follower transistors may have respective lengths—each length measured along a line between a respective transistor source and a respective transistor drain—which when combined are larger than (for example, double) a corresponding length of a single source follower transistor in a conventional pixel cell architecture. Correspondingly, the two source follower transistors may together have a comparatively large aggregate region of interface between active area(s) for the two source follower transistors and one or more isolation structures adjoining the active area(s).

However, the gates of the two source follower transistors may have respective widths—e.g. each width measured athwart a respective transistor length—which when combined are larger than (for example, double) the width of a single source follower transistor gate in a conventional pixel cell architecture. This may be the case even where one or both of the two source follower transistor gates are not individually wider than a source follower transistor gate in a conventional pixel cell. The large aggregate width of the source follower transistor gates in a pixel cell according to an embodiment may provide for large drive current for the two source follower transistors. This large drive current may more than offset any increase in RTS noise due to the relatively large aggregate region of interface between active area(s) and adjoining isolation structure(s). Alternatively or in addition, the two source follower transistors may each contribute respective RTS noise components which at least partially cancel each other out, although certain embodiments are not limited in this regard.

For each of the two source follower transistors, operation of the source follower transistor to provide a respective contribution to an amplification signal may be based on a respective value of a voltage difference Vgs between the gate of the source follower transistor and the source of that source follower transistor. At least one advantage of various embodiments is that, to provide an amplification signal having a given amplification level, the respective Vgs values of the two source follower transistors may each be less than (e.g. half of) a corresponding Vgs value of a single source follower transistor in a conventional pixel cell to provide such an amplification signal. Charge trap events, and RTS noise resulting from such events, tend to increase in number with increasing Vgs values of a transistor. Consequently, when it comes to providing an amplification signal having a given amplification level, a pixel cell according to an embodiment may provide a comparative advantage over a conventional pixel cell, at least in terms of total charge trapping (and RTS noise) occurring in their respective source follower transistors.

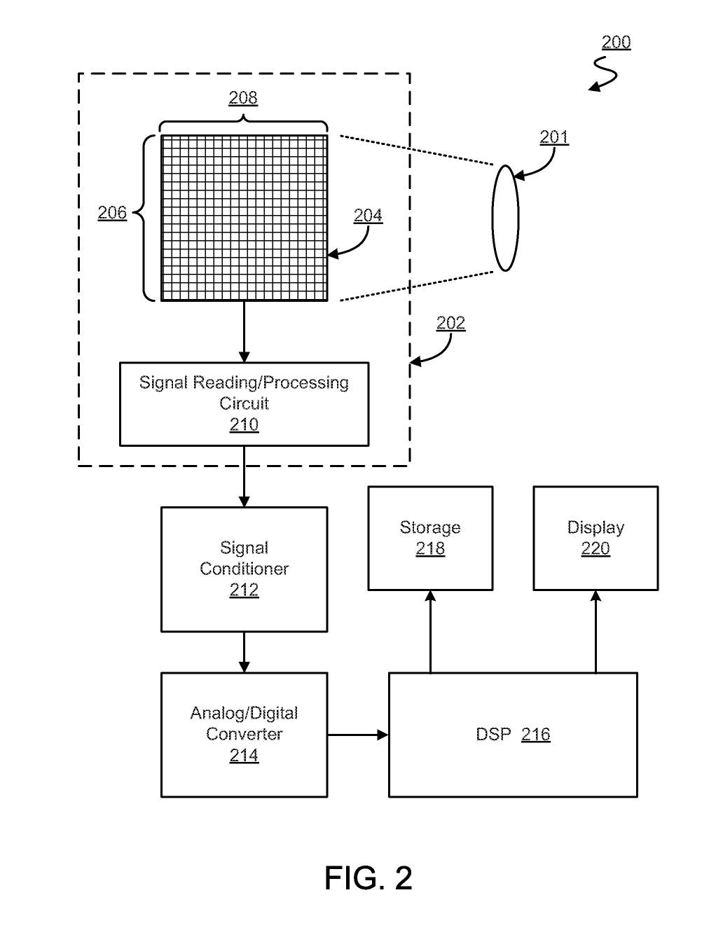

FIG. 2 illustrates elements of an imaging system 200 according to an embodiment. Optics 201, which can include refractive, diffractive or reflective optics or combinations of these, may couple to image sensor 202 to focus an image onto the pixels in pixel array 204 of the image sensor. Pixel array 204 may capture the image and the remainder of imaging system 200 may process the pixel data from the image. By way of illustration and not limitation, image sensor 202 may comprise a pixel array 204 and a signal reading and processing circuit 210. Image sensor 202 may, for example, include a pixel array 204 comprising a plurality of pixels arranged in rows 206 and columns 208. During operation of pixel array 204 to capture an image, one or more pixels in pixel array 204 may capture incident light (i.e., photons) during a certain exposure period and convert the collected photons into an electrical charge. As discussed herein, one or more pixels of pixel array 204 may each include respective dual source follower transistors. The electrical charge generated by each pixel may be read out as an analog signal—e.g. where a characteristic of the analog signal such as its charge, voltage or current is representative of the intensity of light that was incident on the pixel during the exposure period. Illustrated pixel array 204 is regularly shaped, but in other embodiments the array may have a regular or irregular arrangement different than shown and can include more or less pixels, rows, and columns than shown. Moreover, in different embodiments pixel array 204 may be a color image sensor including red, green, and blue pixels designed to capture images in the visible portion of the spectrum, or may be a black-and-white image sensor and/or an image sensor designed to capture images in the invisible portion of the spectrum, such as infra-red or ultraviolet.

In an embodiment, image sensor 202 includes signal reading and processing circuit 210. Among other things, circuit 210 may include circuitry and logic that methodically reads analog signals from each pixel, filters these signals, corrects for defective pixels, and so forth. In an embodiment where circuit 210 performs only some reading and processing functions, the remainder of the functions may be performed by one or more other components such as signal conditioner 212 or DSP 216. Although shown in FIG. 2 as an element separate from pixel array 204, in some embodiments reading and processing circuit 210 may be integrated with pixel array 204 on the same substrate or may comprise circuitry and logic embedded within the pixel array. In other embodiments, however, reading and processing circuit 210 is an element external to pixel array 204 as shown in FIG. 2. In still other embodiments, reading and processing circuit 210 may be an element not only external to pixel array 204, but also external to image sensor 202.

Signal conditioner 212 may be coupled to image sensor 202 to receive and condition analog signals from pixel array 204 and reading and processing circuit 210. In different embodiments, signal conditioner 212 may include various components for conditioning analog signals. Examples of components that may be found in the signal conditioner include filters, amplifiers, offset circuits, automatic gain control, etc. In an embodiment where signal conditioner 212 includes only some of these elements and performs only some conditioning functions, the remaining functions may be performed by one or more other components such as circuit 210 or DSP 216. Analog-to-digital converter (ADC) 214 may be coupled to signal conditioner 212 to receive conditioned analog signals corresponding to each pixel in pixel array 204 from signal conditioner 212 and convert these analog signals into digital values.

Digital signal processor (DSP) 216 may be coupled to analog-to-digital converter 214 to receive digitized pixel data from ADC 214 and process the digital data to produce a final digital image. DSP 216 may include a processor and an internal memory in which it may store and retrieve data. After the image is processed by DSP 216, it may be output to one or both of a storage unit 218 such as a flash memory or an optical or magnetic storage unit and a display unit 220 such as an LCD screen.

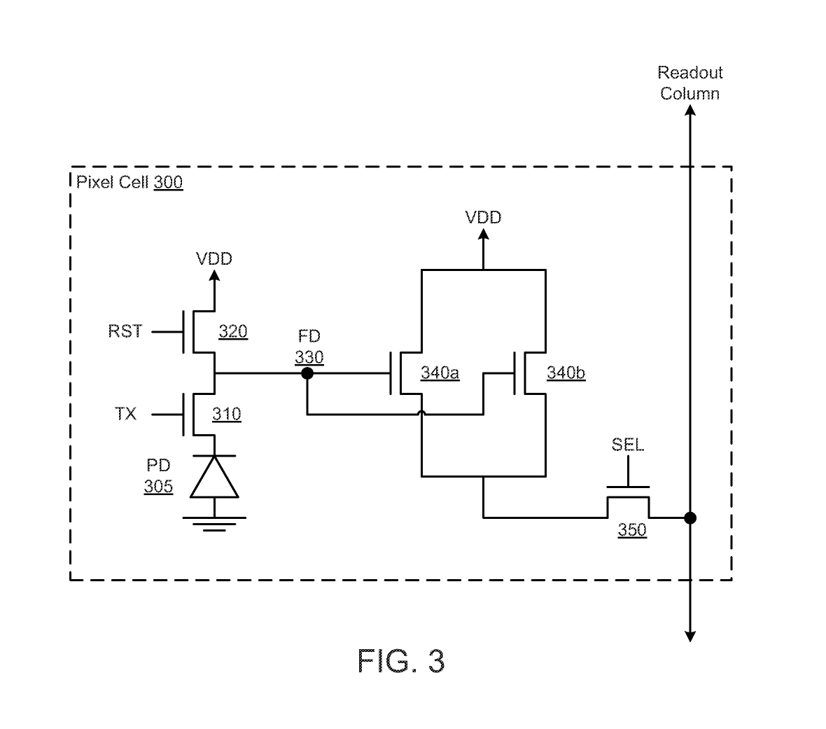

FIG. 3 is a circuit diagram showing circuitry 300 of a pixel cell 300 having dual source follower transistors according to an embodiment. In FIG. 3, pixel cell 300 may be arranged to provide an output to a readout column signal line, although certain embodiments are not limited in this regard. In an embodiment the illustrative pixel cell 300 includes a photosensitive element PD 305, a transfer transistor 310, a reset transistor 320, a first source-follower transistor 340a, a second source-follower transistor 340b, and a select transistor 350. However, pixel cell 300 may include any of a variety of alternative pixel cell architectures, according to different embodiments, in which two source follower transistors are coupled to a floating diffusion node in a configuration similar to that of first source-follower transistor 340a and second source-follower transistor 340b.

During operation of pixel cell 300, transfer transistor 310 may receive a transfer signal TX, which transfers charge accumulated in PD 305 to a floating diffusion node FD 330. Reset transistor 320 may be coupled between a power supply VDD and FD 330 to reset the pixel (e.g., to discharge or charge FD 330 and/or PD 305 to a preset voltage) under control of a reset signal RST. FD 330 may also be coupled to control the gate of first source follower transistor 340a. First source follower transistor 340a may be coupled between power supply VDD and select transistor 350. First source follower transistor 340a may operate as a source-follower providing a high impedance connection to FD 330. Moreover, FD 330 may also be coupled to control the gate of second source follower transistor 340b, which is also coupled between power supply VDD and select transistor 350. Second source follower transistor 340b may operate as a second source-follower, coupled to operate electrically in parallel with first source follower transistor 340a, to provide another high impedance connection to FD 330.

In an embodiment, first source follower transistor 340a and second source follower transistor 340b each provide a respective component of an amplification signal—e.g. where the amplification signal is received by select transistor 350. By way of illustration and not limitation, select transistor 350 may, under control of a select signal SEL, selectively receive the amplification signal and provide an output of pixel cell 300 to the readout column line. In an alternate embodiment, a pixel cell does not include any select transistor—e.g. where the respective component signals from dual source follower transistors of the pixel cell are combined and output directly to a readout column line. In such an embodiment, the amplification signal to which the dual source follower transistors each contribute is itself the analog output signal of the pixel cell.

PD 305 and FD 330 may be reset by temporarily asserting the reset signal RST and the transfer signal TX. An image accumulation window (exposure period) may be commenced by de-asserting the transfer signal TX and permitting incident light to charge PD 305. As photo-generated electrons accumulate on PD 305, its voltage may decrease. The voltage or charge on PD 305 may be indicative of the intensity of the light incident on PD 305 during the exposure period. At the end of the exposure period, the reset signal RST may be de-asserted to isolate FD 330 and the transfer signal TX may be asserted to allow an exchange of charge between PD 305 and FD 330, and hence to the respective gates of both first source follower transistor 340a and second source follower transistor 340b. The charge transfer causes the voltage of FD 330 to change by an amount which is proportional to photogenerated electrons accumulated on PD 305 during the exposure period. This second voltage biases both first source follower transistor 340a and second source follower transistor 340b which, together with each other and in combination with the select signal SEL being asserted, may drive a signal from select transistor 350 to the readout column line. Data may then be readout from pixel cell 300 onto the readout column line as an analog signal.

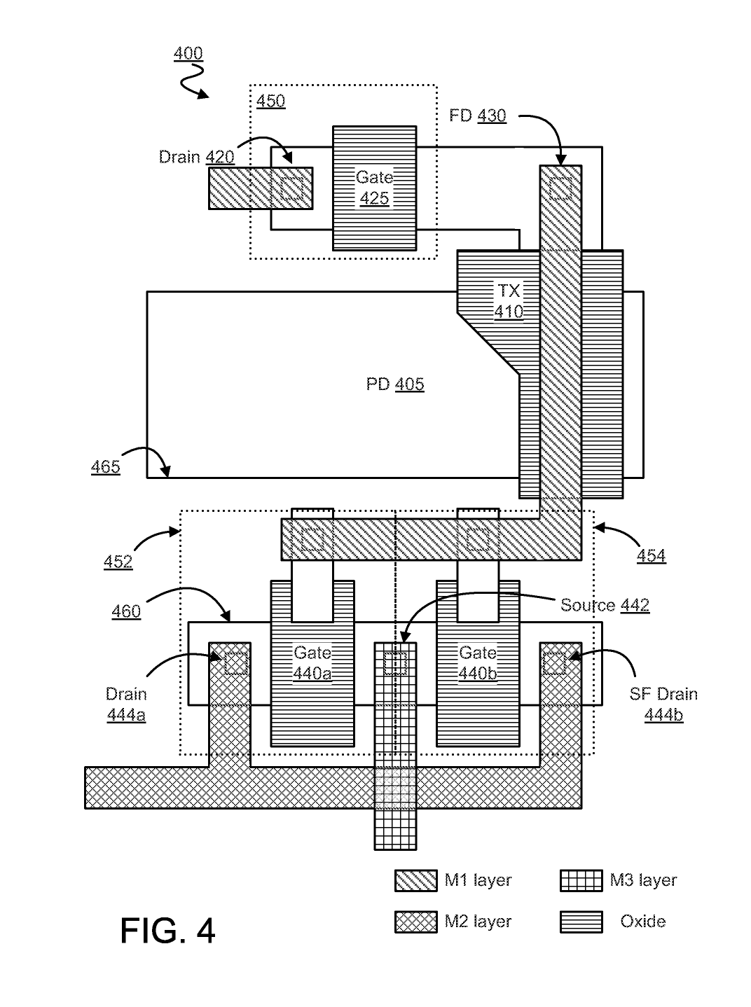

FIG. 4 shows a layout of certain circuit elements in a pixel cell 400 having dual source follower transistors according to an embodiment. Pixel cell 400 may operate in a pixel array having some or all of the features of pixel array 204, for example. In an embodiment, pixel cell 400 includes some or all of the features of pixel cell 300.

By way of illustration and not limitation, pixel cell 400 may include a photosensitive element PD 405, a transfer transistor 410, a reset transistor 450, a first source-follower transistor 452, and a second source-follower transistor 454. However, pixel cell 400 may include any of a variety of alternative pixel cell architectures, according to different embodiments, in which two source follower transistors are each coupled via their respective gates to the same floating diffusion node. In an embodiment, the functionality of PD 405, transfer transistor 410, reset transistor 450, first source-follower transistor 452, and second source-follower transistor 454 correspond, respectively, to the functionality of PD 305, transfer transistor 310, reset transistor 320, first source-follower transistor 340a and second source-follower transistor 340b. Pixel cell 400 may further include a select transistor (not shown)—e.g. a transistor including some or all of the features of select transistor 350—although certain embodiments are not limited in this regard.

During operation of pixel cell 400, transfer transistor 410 may receive a transfer signal TX, which transfers charge accumulated in PD 405 to a floating diffusion node FD 430. A drain 420 of reset transistor 450 may be coupled, for example, to a power supply VDD (not shown). In an embodiment, reset transistor 450 may further couple directly to FD 430—e.g. where a source (not shown) of reset transistor 450 outputs charge directly into an active area which includes FD 430. In such a configuration, reset transistor 450 may be operable to reset pixel cell 400 (e.g., to discharge or charge FD 430 and/or PD 405 to a preset voltage) under control of a reset signal provided to a gate 425 of reset transistor 450. FD 430 may also be coupled to control both a gate 440a of source follower transistor 452 and a gate 440b of source follower transistor 454—e.g. via a metal trace which extends over transfer transistor 410. The respective metal layers of various traces shown for pixel cell 400 are merely illustrative, and are not limiting on certain embodiments.

Source follower transistor 452 and source follower transistor 454 may each be coupled between a power supply VDD (not shown) and common source follower output trace. By way of illustration and not limitation, a drain 444a of source follower transistor 452 and a drain 444b of source follower transistor 454 may each couple to a metal trace for power supply VDD. In an embodiment, source follower transistor 452 and source follower transistor 454 may further share a single source 442 for each to output a respective current component.

Source follower transistor 452 and source follower transistor 454 may each operate as a respective source-follower providing a high impedance connection to FD 430. In one embodiment, shared source 442 may provide a direct output from pixel cell 400 to a readout bitline (not shown). In another embodiment, shared source 442 may couple to a select transistor (not shown) of pixel cell 400—e.g. where a select signal SEL provided at a gate of such a select transistor selectively provides an output of pixel cell 400 to a readout bitline.

Source follower transistor 452 and source follower transistor 454 may share an active area 460 disposed in a semiconductor substrate for pixel cell 400, although certain embodiments are not limited in this regard. By way of illustration and not limitation, source follower transistor 452 and source follower transistor 454 may each have one or more respective components which are variously formed in and/or on active area 460. Active area 460 may adjoin one or more shallow trench isolation structures (not shown) of pixel cell 400. The particular size and shape of active area 460 is merely illustrative, and is not limiting on certain embodiments. In an embodiment, operation of source follower transistor 452 to provide a first amplification signal component may form a channel to carry current in a first direction in active area 460—e.g. where current flows from shared source 442 through a channel under gate 440a to drain 444a. Additionally or alternatively, operation of source follower transistor 454 to provide a second amplification signal component may form a channel to carry current in a second direction in active area 460 which is opposite the first direction—e.g. where current flows from shared source 442 through a channel under gate 440b to drain 444b.

Either or each of the respective channels of source follower transistors 452, 454 may have a respective channel length which is shorter than the channel length of a solitary source follower transistor in a conventional pixel cell architecture. By way of illustration and not limitation, PD 405 may include a side 465 which is a closest of the sides of PD 405 to source follower transistors 452, 454—e.g. where source follower transistors 452, 454 are in line with one another along a line which parallels side 465. The length of side 465 may, in an embodiment, be at least as long as a combined length of source follower transistors 452, 454, as measured along a path which parallels side 465. In such an embodiment, the respective channels of source follower transistors 452, 454 may each have a length which, as measured along a path which parallels side 465, is less than half of side 465—e.g. less than 25% the length of side 465.

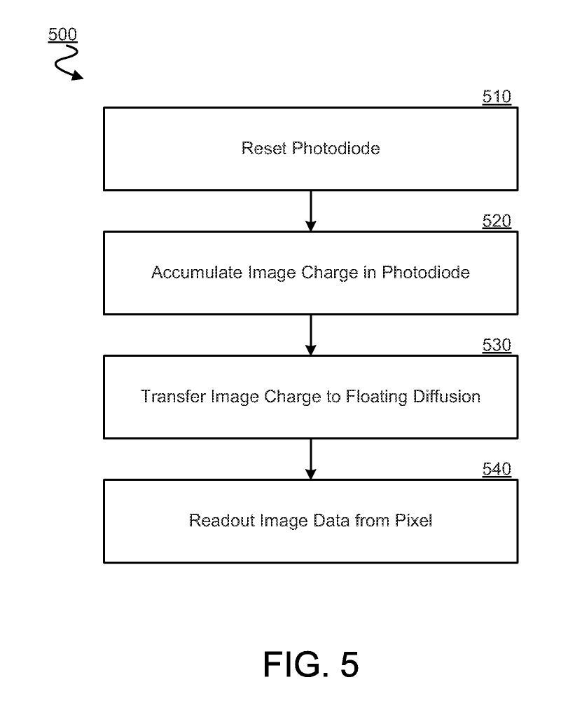

FIG. 5 is a flow chart illustrating elements of a process 500 for operating a pixel cell including dual source followers in accordance with an embodiment. Process 500 may implement operation of pixel cell 300, for example. In an embodiment, process 500 may be sequentially or concurrently executed with multiple respective pixels in pixel array 204—e.g. depending upon whether a rolling shutter or global shutter is used. The order in which some or all of the process blocks appear in process 500 should not be deemed limiting. Rather, one of ordinary skill in the art having the benefit of the present disclosure will understand that some of the process blocks may be executed in a variety of orders not illustrated.

In a process block 510, a photodiode (e.g., photodiode region PD 305) may be reset. Resetting may include discharging or charging photodiode to a predetermined voltage potential. Such reset may be achieved by asserting both a reset signal and a transfer signal—e.g. a reset signal RST to enable reset transistor 320 and a transfer signal TX to enable transfer transistor 310. Enabling a reset transistor and transfer transistor of the pixel cell may electrically couple the photodiode and a floating diffusion node of the pixel cell to a reset power line—e.g. a power rail VDD.

After the photodiode is reset, image acquisition by the photodiode may commence, at process block 520. For example, the reset signal and/or the transfer signal may be de-asserted to electrically isolate the photodiode for charge accumulation therein. In an embodiment, light incident on the pixel cell may be focused by a microlens and/or pass through a color filter layer onto the photodiode region. Such a color filter may operate to filter the incident light into component colors (e.g., using a Bayer filter mosaic or color filter array). The incident photons may cause charge to accumulate within the photodiode.

Once the image acquisition window has expired, the accumulated charge within the photodiode may, at process block 530, be transferred to the floating diffusion node—e.g. by asserting a transfer signal to the gate of the transfer transistor. In the case of a global shutter, the global shutter signal may be asserted simultaneously, as the transfer signal, to all pixels within pixel array 204 during process block 520. This may result in a global transfer of the respective image data accumulated by each pixel into the pixel's corresponding floating diffusion 450.

Once the image data is transferred, the transfer signal may be de-asserted to isolate the floating diffusion node from the photodiode, in preparation for a readout of image data from the pixel cell at process block 540. In an embodiment, the readout at block 540 may include a voltage of the floating diffusion node activating dual source follower transistors (e.g. source follower transistors 340a, 340b) coupled thereto. Such source follower transistors may, for example, be coupled in parallel with one another to a bitline for directly reading out the image data to the bitline as an analog signal. In various embodiments, readout may occur on a per row basis via column lines, on a per column basis via row lines, on a per pixel basis, or by other logical groupings. Once the image data of all pixels has been readout, process 500 may, in an embodiment, return to process block 510 to prepare for the next image.

Techniques and architectures for generating image data are described herein. In the above description, for purposes of explanation, numerous specific details are set forth in order to provide a thorough understanding of certain embodiments. It will be apparent, however, to one skilled in the art that certain embodiments can be practiced without these specific details. In other instances, structures and devices are shown in block diagram form in order to avoid obscuring the description.

Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

Some portions of the detailed description herein are presented in terms of algorithms and symbolic representations of operations on data bits within a computer memory. These algorithmic descriptions and representations are the means used by those skilled in the computing arts to most effectively convey the substance of their work to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the discussion herein, it is appreciated that throughout the description, discussions utilizing terms such as “processing” or “computing” or “calculating” or “determining” or “displaying” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Certain embodiments also relate to apparatus for performing the operations herein. This apparatus may be specially constructed for the required purposes, or it may comprise a general purpose computer selectively activated or reconfigured by a computer program stored in the computer. Such a computer program may be stored in a computer readable storage medium, such as, but is not limited to, any type of disk including floppy disks, optical disks, CD-ROMs, and magnetic-optical disks, read-only memories (ROMs), random access memories (RAMs) such as dynamic RAM (DRAM), EPROMs, EEPROMs, magnetic or optical cards, or any type of media suitable for storing electronic instructions, and coupled to a computer system bus.

The algorithms and displays presented herein are not inherently related to any particular computer or other apparatus. Various general purpose systems may be used with programs in accordance with the teachings herein, or it may prove convenient to construct more specialized apparatus to perform the required method steps. The required structure for a variety of these systems will appear from the description herein. In addition, certain embodiments are not described with reference to any particular programming language. It will be appreciated that a variety of programming languages may be used to implement the teachings of such embodiments as described herein.

Besides what is described herein, various modifications may be made to the disclosed embodiments and implementations thereof without departing from their scope. Therefore, the illustrations and examples herein should be construed in an illustrative, and not a restrictive sense. The scope of the invention should be measured solely by reference to the claims that follow.

What is claimed is:

1. A pixel array comprising:
a pixel cell to output an analog signal based on an amplification signal, the pixel cell comprising:
a photodiode to accumulate charge in response to light incident upon the photodiode;
a transfer transistor coupled between the photodiode and a floating diffusion node, the transfer transistor to bring the floating diffusion node to a voltage level based on the accumulated charge;
a first source follower transistor including a first gate coupled to the floating diffusion node, the first source follower transistor to output, based on the voltage level, a first component of the amplification signal; and
a second source follower transistor including a second gate coupled to the floating diffusion node, the second source follower transistor to output, based on the voltage level, a second component of the amplification signal.

2. The pixel array of claim 1, wherein a terminal of the first source follower transistor is coupled directly to a terminal of the second source follower transistor at a first node, wherein the amplification signal is provided at the first node.

3. The pixel array of claim 1, wherein the first source follower transistor and the second source follower transistor are in line with one another along a line which parallels a first side of the photodiode, wherein the first side is a closest of any side of the photodiode to the first source follower transistor and the second source follower transistor.

4. The pixel array of claim 3, wherein the first source follower transistor to output the first component of the amplification signal includes the first source follower transistor to carry charge in a first channel of the first transistor along a first direction, wherein the second source follower transistor to output the second component of the amplification signal includes the second source follower transistor to carry charge in a second channel of the second transistor along a second direction opposite the first direction.

5. The pixel array of claim 1, wherein the analog signal is the amplification signal.

6. The pixel array of claim 1, further comprising a row select transistor coupled to the first source follower transistor and to the second source follower transistor, the row select transistor including a third gate to receive a row select signal, the row select transistor to receive the amplification signal and to output the analog signal based on the row select signal.

7. The pixel array of claim 1, wherein the first source follower transistor and the second source follower transistor share a common source terminal.

8. An image sensor system comprising:
a pixel array including:
a pixel cell to output an analog signal based on an amplification signal, the pixel cell comprising:
a photodiode to accumulate charge in response to light incident upon the photodiode;
a transfer transistor coupled between the photodiode and a floating diffusion node, the transfer transistor to bring the floating diffusion node to a voltage level based on the accumulated charge;
a first source follower transistor including a first gate coupled to the floating diffusion node, the first source follower transistor to output, based on the voltage level, a first component of the amplification signal; and
a second source follower transistor including a second gate coupled to the floating diffusion node, the second source follower transistor to output, based on the voltage level, a second component of the amplification signal; and
readout circuitry coupled to read out image data from the pixel array.

9. The image sensor system of claim 8, wherein a terminal of the first source follower transistor is coupled directly to a terminal of the second source follower transistor at a first node, wherein the amplification signal is provided at the first node.

10. The image sensor system of claim 8, wherein the first source follower transistor and the second source follower transistor are in line with one another along a line which parallels a first side of the photodiode, wherein the first side is a closest of any side of the photodiode to the first source follower transistor and the second source follower transistor.

11. The image sensor system of claim 10, wherein the first source follower transistor to output the first component of the amplification signal includes the first source follower transistor to carry charge in a first channel of the first transistor along a first direction, wherein the second source follower transistor to output the second component of the amplification signal includes the second source follower transistor to carry charge in a second channel of the second transistor along a second direction opposite the first direction.

12. The image sensor system of claim 8, wherein the analog signal is the amplification signal.

13. The image sensor system of claim 8, the pixel cell further comprising a row select transistor coupled to the first source follower transistor and to the second source follower transistor, the row select transistor including a third gate to receive a row select signal, the row select transistor to receive the amplification signal and to output the analog signal based on the row select signal.

14. The image sensor system of claim 8, wherein the first source follower transistor and the second source follower transistor share a common source terminal.

15. A method at a pixel cell of a pixel array, the method comprising:
accumulating charge at a photodiode in response to light incident upon the photodiode;
with a transfer transistor coupled between the photodiode and a floating diffusion node, bringing the floating diffusion node to a voltage level based on the accumulated charge;
outputting from a first source follower transistor a first component of the amplification signal, the first source follower transistor including a first gate coupled to the floating diffusion node, the outputting the first component based on the floating diffusion node being brought to the voltage level; and
outputting from a second source follower transistor a second component of the amplification signal, the second source follower transistor including a second gate coupled to the floating diffusion node, the outputting the second component based on the floating diffusion node being brought to the voltage level;
wherein the pixel cell outputs an analog signal based on the amplification signal.

16. The method of claim 15, wherein a terminal of the first source follower transistor is coupled directly to a terminal of the second source follower transistor at a first node, wherein the amplification signal is provided at the first node.

17. The method of claim 15, wherein the first source follower transistor and the second source follower transistor are in line with one another along a line which parallels a first side of the photodiode, wherein the first side is a closest of any side of the photodiode to the first source follower transistor and the second source follower transistor.

18. The method of claim 15, wherein the analog signal is the amplification signal.

19. The method of claim 15, further comprising:
providing a row select signal to a third gate of a row select transistor coupled to the first source follower transistor and further to the second source follower transistor, wherein, based on the row select signal, the row select transistor receives the amplification signal and outputs the analog signal.

20. The method of claim 15, wherein the first source follower transistor and the second source follower transistor share a common source terminal.
